(19) United States
(12) Patent Application Publication
(10) Pub. No.: US 2011/0175098 A1
(43) Pub. Date: Jul. 21, 2011

(54) LIGHT EMITTING ELEMENT AND DISPLAY DEVICE

(76) Inventors: Masayuki Ono, Osaka (JP); Reiko Taniguchi, Osaka (JP); Eiichi Satoh, Osaka (JP); Takayuki Shimamura, Osaka (JP); Masaru Odagiri, Hyogo (JP)

(21) Appl. No.: 13/120,820

(22) PCT Filed: Apr. 30, 2009
(86) PCT No.: PCT/JP2009/001955

§ 371 Date: Mar. 24, 2011

(30) Foreign Application Priority Data
Sep. 25, 2008 (JP) 2008-246072

(51) Int. Cl. H01L 33/08; H01L 33/50; H01L 33/16

(52) U.S. Cl. 257/59; 257/98; 257/72; 257/E33.061; 257/E33.053; 257/E33.004

(57) ABSTRACT

A light emitting element includes: a first electrode and a second electrode provided as being opposed each other, at least one of the first electrode and the second electrode being transparent or translucent; and a phosphor layer sandwiched between the first electrode and the second electrode, from a direction that is perpendicular to main surfaces of the first and second electrodes. In this structure, the phosphor layer includes: a plurality of phosphor particles that are disposed within a plane of the phosphor layer; and a first and second insulating guides that sandwich two sides of each of the phosphor particles from a direction that is in parallel with the surface of the phosphor layer.

### BACKGROUND

1. Technical Field

This application claims the priority of Japanese Patent Application No. 2008-246072 filed in Japan on Sep. 25, 2008, the contents of which are hereby incorporated by reference.

The present invention relates to a light emitting element that is applicable to various kinds of light sources for use in flat panel display devices, communication devices, illumination devices and the like, and a display device using such a light emitting element.

2. Background Art

In recent years, various kinds of flat panel display devices have been proposed and put into practical use. Among these, an electroluminescence (hereinafter, referred to simply as “EL”) element serving as a plane light source has been highly expected in its utility value as a backlight for a liquid crystal display, or as a matrix-type display device in which the EL elements are disposed in an array form. For example, the matrix-type display device using the EL elements is allowed to exhibit spontaneous light emitting characteristics, and has advantages such as superior visibility, a wide viewing angle and a fast response. However, in the case of an organic EL element in which an organic material is used as a phosphor material, there is a tendency that sufficient long-term reliability as a display device is hardly obtained, and in the case of an inorganic EL element in which an inorganic material is used as a phosphor material, there is a tendency that sufficient luminance and efficiency are hardly obtained; thus, only applications to these limited specific fields are available.

Meanwhile, light emitting diodes (hereinafter, referred to simply as “LED”) that have been put into practical use as light sources with high luminance and high efficiency can also be considered as EL elements in a wide sense. In recent years, the LED's have been widely utilized because of development of high-intensity blue and green light emitting elements. However, the LED's have only been put into practical use as dot light sources, and the applications thereof to display devices such as displays are only limited to back-light-use light sources for liquid crystal displays, and the like.

Among those semiconductor materials to be used as these LED's, group 13 nitride semiconductors typified by GaN have drawn public attentions. These group 13 nitride semiconductors have a wide band gap, and light emission covering from an ultraviolet range to a visible light range is available depending on its compositions. Moreover, since those materials belong to a direct-transition type and have an effective energy band structure as a light emitting material, they have superior characteristics such as high light emitting efficiency. Moreover, conventionally, group 13 nitride semiconductors are mainly formed by epitaxial growth on a sapphire substrate having a main plane as a c-plane ((0, 0, 0, 1) plane); however, in recent years, studies and development have been vigorously carried out so as to form these semiconductors on a substrate having a plane orientation other than the c-plane, as described in Japanese Patent Laid-open Publication No. 7-297495 A, Japanese Patent Laid-open Publication No. 2001-160656 A, and Japanese Patent Laid-open Publication No. 2003-92426 A. In the case of a group 13 nitride semiconductor formed on the c-plane, a crystal is grown with the c-plane (polar plane) serving as an epitaxial plane, resulting in a problem that a strong inner electric field is formed by piezoelectric polarization and spontaneous polarization that are generated by strains in the crystal structure. In the case of the LED's, these cause electrons and holes to be injected into the light emitting layer to be separated from each other, resulting in a reduction in the recombination probability. The above-mentioned Japanese Patent Laid-open Publication No. 7-297495 A, Japanese Patent Laid-open Publication No. 2001-160656 A, and Japanese Patent Laid-open Publication No. 2003-92426 A, which attempt to solve these problems, have processes in which, by forming the semiconductor on a substrate having a plane orientation other than the c-plane, a crystal is grown, with a non-polar plane (a-plane or m-plane) or a semi-polar plane (r-plane) serving as an epitaxial plane, so that it becomes possible to achieve higher efficiency by excluding the influences of the inner electric field.

In the case of group 13 nitride semiconductors, however, even when grown on a sapphire substrate, the lattice mismatching rate thereof is about 1000 times worse than that of the other semiconductor devices, with the result that the through dislocation density thereof becomes higher by about 5 digits, and because of reasons such as being formed as a thin film epitaxially grown on a substrate by using a metal-organic vapor phase epitaxy method (hereinafter, referred to simply as “MOVPE”), it becomes difficult to apply these to a light emitting element with a large area from the viewpoints of performance and costs.

In order to overcome these shortcomings of the LED, a method has been proposed in which particle-shaped or pillar-shaped materials of group 13 nitride semiconductors are formed, as described in Japanese Patent Laid-open Publication No. 2007-95685 A. For example, according to the method described in Patent Document 4, a light emitting element in which a semiconductor nano crystal, mainly composed of any one of groups 13 to 15 compound semiconductors, is used as a phosphor, and driven by a direct current has been proposed. In the light emitting element in which the light emitting layer is composed of phosphor particles, by using processes in which particles are formed by using a high-temperature thermal process and then the resulting particles are applied to a general-use glass substrate, it becomes possible to easily provide a large-area device.

FIG. 9 is a schematic structural drawing that illustrates a light emitting element that utilizes a nano crystal of GaN. A light emitting element 100 has a structure in which, on a substrate 101, an anode 102, a hole transporting layer 103, a light emitting layer 104, an electron transporting layer 105, and a cathode 106 are stacked in this order. Moreover, the light emitting layer 104 is composed of semiconductor nano crystals 104a mainly made from any one of groups 13 to 15 compound semiconductors or the like, and an insulating filling substance 104b. The anode 102 and the cathode 106 are electrically connected to each other with a power supply 107 being interposed therebetween, and when a voltage is applied to the power supply 107, holes are injected into the hole transporting layer 103 from the anode 102, while electrons are injected into the electron transporting layer 105 from the cathode 106, respectively. Next, holes and electrons are injected into the semiconductor nano crystal 104a inside the light emitting layer 104. As a result, recombination of a hole and an electron takes place inside the semiconductor nano crystal 104a, with the result that light emission derived from the semiconductor nano crystal is generated. The light emission is taken out of the light emitting element through the anode 102.

### SUMMARY OF THE INVENTION

However, in the case of the nano crystal as proposed above, because of the reasons that aggregation occurs due to an intermolecular force, that defects are generated by an increase of the surface area, and that crystal grains each having a polar plane and a non-polar plane are filled with indefinite plane orientations to be subjected to influences from an inner electric field, the light emission luminance and light emission efficiency are lowered, failing to achieve a satisfactory level in practical use.

An object of the present invention is to provide a dc-driving type light emitting element in which phosphor particles mainly composed of a group 13 nitride semiconductor are used, and which has high luminance and high efficiency, and is easily formed into a plane shape, and a display device using such a light emitting element.

The light emitting element according to the present invention includes:

a first electrode and a second electrode provided as being opposed each other, at least one of the first electrode and the second electrode being transparent or translucent; and

a phosphor layer sandwiched between the first electrode and the second electrode, from a direction that is perpendicular to main surfaces of the first and second electrodes,

wherein the phosphor layer includes:

a plurality of phosphor particles that are disposed within a plane of the phosphor layer; and

a first and second insulating guides that sandwich two sides of each of the phosphor particles from a direction that is in parallel with the surface of the phosphor layer.

In addition, the phosphor particles may be disposed such that the longitudinal direction of each phosphor particle is in parallel with the surface of the phosphor layer. Furthermore, the first and second insulating guides may sandwich the two sides in a direction that is perpendicular to the longitudinal direction of each of the phosphor particles from a direction that is in parallel with the surface of the phosphor layer.

In addition, each of the phosphor particles may be made of a compound semiconductor having a crystal structure of a hexagonal system. Furthermore, each of the phosphor particles may be made of a nitride semiconductor containing at least one element selected from the group consisting of Ga, Al and In. Still further, each of the phosphor particles may satisfy the relational expression, such as L1<L2, L1 being a length of the phosphor particle along a direction that is in parallel with a c-plane and L2 being a length L2 of the phosphor particle along a direction that is perpendicular to c-plane. The c-axis direction of each of the phosphor particles may be substantially in parallel with the surface of the phosphor layer.

In addition, the first and second insulating guides may have a resistivity along a direction perpendicular to the surface of the phosphor layer being higher than a resistivity of each of the phosphor particles along a direction perpendicular to the surface of the phosphor layer.

Each of the first and second insulating guides may have a plane portion that is in parallel with the main surface of the electrode selected from the first and second electrodes, and

the plane portion may have at least one portion thereof as being in contact with the main surface of the electrode. Furthermore, the first insulating guide and the second insulating guide that sandwich the two sides of each of the phosphor particles may have a gap that is wider than a width of the phosphor particle along a direction orthogonal to a c-axis of an m-plane of the phosphor particle.

The light emitting element may further include: a hole transporting layer that is sandwiched between the phosphor particles and the electrode that is selected from the first electrode and the second electrode. The light emitting element may further include: a supporting substrate that faces at least one of the first electrode and the second electrode, and supports the first and second electrodes.

Furthermore, the light emitting element may further include one or more thin-film transistors that are connected to at least one of the first electrode and the second electrode.

A display device according to the present invention is provided with:

a light emitting element array on which the plurality of light emitting elements are two-dimensionally arranged;

a plurality of x electrodes that are extended in parallel with one another in a first direction in parallel with a light emitting surface of the light emitting array; and

a plurality of y electrodes that are extended in parallel with one another in a second direction orthogonal to the first direction, in parallel with the light emitting surface of the light emitting element array.

A display device according to the present invention is provided with:

a light emitting element array on which the plurality of light emitting elements are two-dimensionally arranged;

a plurality of signal lines that are extended in parallel with one another in a first direction in parallel with the light emitting surface of the light emitting element array; and

a plurality of scanning lines that are extended in parallel with a second direction orthogonal to the first direction, in parallel with the light emitting surface of the light emitting element array,

wherein one of the electrodes that are connected to the thin film transistor of the light emitting element array corresponds to pixel electrode placed on each of intersections between the signal lines and the scanning lines, and

the other one of the electrodes may be commonly provided on the plurality of light emitting elements.

The present invention makes it possible to provide a light emitting element which has high luminance and high efficiency, and is easily formed into a plane shape, and a display device using such a light emitting element.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a cross-sectional view perpendicular to a light emitting surface of a light emitting element in accordance with first embodiment of the present invention;

FIG. 2 is a cross-sectional view perpendicular to a light emitting surface of a light emitting element in accordance with second embodiment of the present invention;

FIGS. 3A to 3C are schematic perspective views that illustrate inner structures of a phosphor particle in accordance with the present invention;

FIGS. 4A to 4C are cross-sectional views that illustrate manufacturing processes of a guide portion in accordance with the present invention;

FIG. 5A is a schematic view that illustrates a structure of an HVPE device to be used when an n-type semiconductor layer of a phosphor particle is formed;

FIG. 5B is a schematic view that illustrates a structure of an HVPE device to be used when a p-type semiconductor layer of a phosphor particle is formed;

FIG. 6 is a schematic perspective view that illustrates a light emitting element in accordance with third embodiment of the present invention;

FIG. 7 is a schematic perspective view that illustrates a display device in accordance with fourth embodiment of the present invention;

FIG. 8 is a schematic perspective view that illustrates a display device in accordance with fifth embodiment of the present invention; and

FIG. 9 is a cross-sectional view perpendicular to a light emitting surface of a conventional light emitting element.

### DETAILED DESCRIPTION OF THE PREFERRED EMBODIMENTS

A light emitting element and a display device using the light emitting element in accordance with embodiments of the present invention will be described referring to the attached drawings. Before the description of the present invention proceeds, it is to be noted that substantially the same members are designated by the same reference numerals throughout the accompanying drawings.

### First Embodiment

### <Schematic Structure of EL Element>

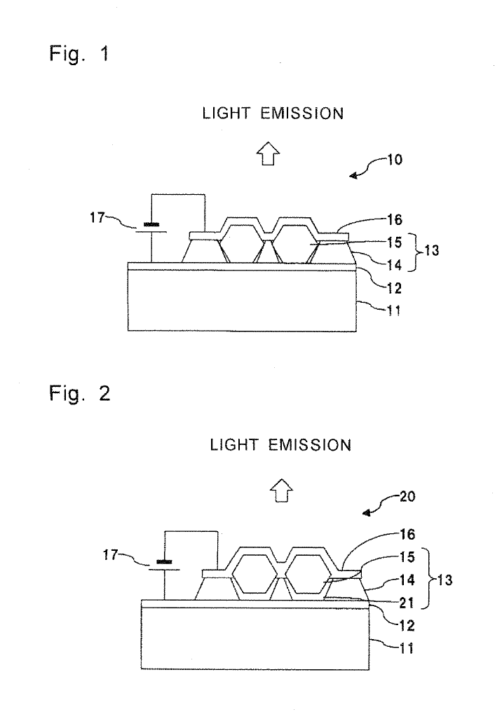

FIG. 1 is a cross-sectional view perpendicular to a phosphor layer 13 that shows a schematic structure of a light emitting element 10 of first embodiment. This light emitting element 10 has a structure in which the phosphor layer 13 containing phosphor particles 15 is sandwiched between a back electrode 12 serving as a first electrode and a transparent electrode 16 serving as a second electrode, while being supported from a direction that is perpendicular to the surfaces of the respective electrodes 12 and 16. As a member that supports these members, a substrate 11 is formed adjacent to the back electrode 12. Moreover, a plurality of guide portions 14, each serving as an insulating structural member, are formed on the back electrode 12 with constant intervals, and a phosphor particle 15 is placed in each gap between the adjacent guide portions 14 in an in-plane direction. The phosphor layer 13 is constituted of these phosphor particles 15 and the guide portions 14 that sandwich the two sides of each phosphor particle 15 from in-plane direction. The back electrode 12 and the transparent electrode 16 are electrically connected to each other with a power supply 17 interposed therebetween. When power is supplied from the power supply 17, a voltage is applied between the back electrode 12 and the transparent electrode 16. At this time, a hole is injected from the back electrode 12 into the phosphor particle 15, while an electron is injected from the transparent electrode 16 into the phosphor particle 15. The hole and the electron are recombined inside the phosphor particle 15 to emit light. The light emission is taken out of the light emitting element 10 through the transparent electrode 16. In the present embodiment, a direct current power supply is used as the power supply 17.

The light emitting element 10 is designed so that light emission is selectively carried out by current paths perpendicular to a non-polar plane of the phosphor particle 15, and it is possible to achieve high luminance and high efficiency, and also to easily form a plane shape.

Without limited to the above-mentioned structure, other revised structures, such as that in which the polarities of the electrodes are positive/negative reversed, that in which a reflective film is further formed on a surface that intersects the substrate surface of each guide portion 14, that in which a member for sealing the entire or a portion of the light emitting element 10 with a resin material or a ceramic material is further provided, that in which a member for color-converting or filtering a light emission color from the phosphor layer 13 is further placed on the front side in the light emission taking-out direction, and that in which, by changing the substrate 11 to a transparent substrate, with the back electrode 12 being changed to a transparent electrode, light emission is taken out from below the light emitting element 10, may be used.

In the following, respective constituent members of the light emitting element will be described in detail.

### <Substrate>

The material for the substrate 11 is not particularly limited; however, in the case where a semiconductor in a phosphor particle is allowed to grow by using the substrate 11, it is necessary to select such a substrate as to be resistant to semiconductor epitaxial processes. Moreover, in the case where, by using phosphor particles formed in another process, a light emitting element is formed by arranging these on a substrate, since no heat resistance or the like is required, a glass substrate, a resin substrate, a film substrate and the like can be used. Furthermore, in order to take out light emission from the phosphor layer, a light transmitting material is desirably selected for the substrate 11. Additionally, the substrate 11 is not necessarily required as long as a shape as the light emitting element can be maintained.

### <Electrode>

The material for the transparent electrode 16 on the light taking-out side is not particularly limited as long as it has a light transmitting property that allows light emission generated inside the phosphor layer 13 to be taken out, and in particular, a material that has high transmittance in a visible light range is preferably used. Moreover, the material preferably has a low resistivity, and is also preferably designed to have superior adhesion to the phosphor layer 13. As the material for the transparent electrode 16, examples of particularly preferable materials include: metal oxides mainly composed of ITO (In₂O₃ doped with SnO₂, referred to also as indium-tin oxide), InZnO, ZnO, SnO₂ or the like; metal thin films made of Pt, Au, Pd, Ag, Ni, Cu, Al, Ru, Rh, Ir, or the like; and conductive polymers, such as polyaniline, polypyrrole, PEDOT/PSS, and polythiophene; however, the material is not particularly limited to these. Moreover, the volume resistivity of the transparent electrode 16 is preferably set to 1×10⁻³Ω·cm or less, the transmittance is preferably set to 75% or more in a wavelength range from 380 to 780 nm, and the refractive index thereof is preferably set to 1.85 to 1.95. For example, in order to improve its transparency or to lower its resistivity, ITO can be formed into a film by using a film-forming method, such as a sputtering method, an electron-beam vapor deposition method or an ion plating method. After the film-forming process, the resulting film may be subjected to a surface treatment, such as a plasma treatment, so as to control the resistivity. The film thickness of the transparent electrode 16 is determined based upon the required sheet resistance value and visible light transmittance.

As the back electrode 12 on the non-light taking-out side, any material may be used as long as it has conductivity and is superior in adhesion to the substrate 11 and the phosphor layer 13. Preferable examples thereof include: metal oxides, such as ITO, InZnO, ZnO and SnO₂; metals, such as Pt, Au, Pd, Ag, Ni, Cu, Al, Ru, Rh, Ir, Cr, Mo, W, Ta, and Nb; and laminated structural members of these; or conductive polymers, such as polyaniline, polypyrrole, PEDOT [poly(3,4-ethylene dioxythiophene)]/PSS (polystyrene sulfonate), or conductive carbon. Moreover, in the case where a conductive substrate, such as an Si substrate or a metal substrate, doped with another element, is used as the substrate 11, the electrode is not necessarily required.

The transparent electrode 16 and the back electrode 12 may exhibit flexibility when formed into films, and may be formed into indefinite shapes in accordance with the shapes of the phosphor particles 15. In this case, a paste, a glass flit or the like, formed by dispersing fine particles made from the above-mentioned conductive material in a resin or the like, may be used. With this arrangement, it is possible to improve the probability of contact point formation between the electrode and the phosphor particles even in the case where there is variation in the shape and the particle size of the phosphor particles 15.

### <Phosphor Layer>

The phosphor layer 13 includes a plurality of phosphor particles disposed in the in-plane direction, and first and second insulating guides formed so as to sandwich the two sides of each phosphor particle from a direction that is in parallel with the surface of the phosphor layer.

### <Phosphor Particle>

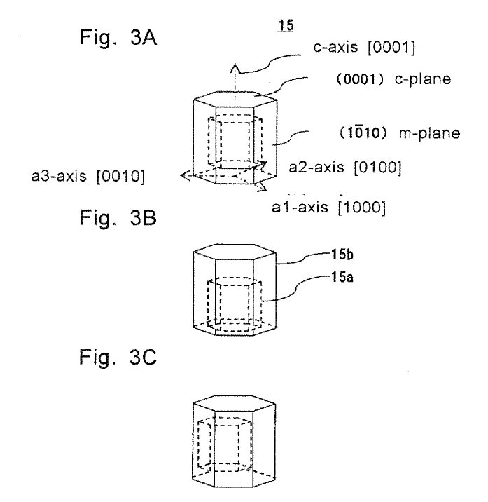

As the phosphor particles 15, a group 13 nitride semiconductor crystal having a wurtzite crystal structure may be used as a host material. Examples thereof include: AlN, GaN, InN, AlₓGa₍₁₋ₓ₎N and In_{y}Ga_{(1-y)}N. Moreover, in order to control the conductivity thereof, one kind or a plurality of kinds of elements, selected from the group consisting of Si, Ge, Sn, C, Be, Zn, Mg, Ge and Mn, may be contained therein as a dopant. Furthermore, these plurality of compositions may be formed into a layer structure or an inclined composition structure inside each phosphor particle 15. FIGS. 3A to 3C are perspective views that show schematic structures of one example of the phosphor particle 15. Each of the phosphor particles 15 is provided with an n-type nucleus particle 15a and a p-type epitaxial layer 15b, and the entire or a portion has a layered structure. Moreover, the phosphor particles 15 are preferably arranged thereon so that a length L2 in a direction perpendicular to the c-plane is set to be longer than a length L1 in a direction in parallel with the c-plane of each particle. When the aspect ratio (L2/L1) between L1 and L2 is large, the phosphor particle 15 and the guide portion 14 can be easily disposed at relative positions in association with each other by its shape-forming effect.

Additionally, the phosphor particles 15, shown in FIGS. 3A to 3C, have a minimum structure that is sufficient to obtain current-exciting-type light emission, and not limited to this structure, the structure may be altered on demand. For example, a semiconductor layer having a band gap narrower than that of the n-type nucleus particle 15a and the p-type epitaxial layer 15b (for example, In_{y}Ga_{(1-y)}N relative to GaN) may be further formed between the n-type nucleus particle 15a and the p-type epitaxial layer 15b so that a double hetero structure may be provided. Moreover, each n-type nucleus particle 15a may be composed of an inner nucleus and an n-type epitaxial layer. In order to accelerate wurtzite crystal growth, the inner nucleus is preferably designed to have a lattice constant and a thermal expansion coefficient that are comparatively close to those of the epitaxial layer, and also to have good crystallinity. In the case where the epitaxial layer is made of GaN, the inner nucleus can be made of different kinds of materials, such as sapphire (Al₂O₃), ZnO, SiC, AlN and spinel (MgAl₂O₄), or GaN that is the same material. Moreover, a buffer layer may be further formed between the inner nucleus and the n-type epitaxial layer.

As the method for forming the epitaxial layer, for example, a publicly known method, such as an MOVPE method, a halide vapor phase epitaxy method (HVPE), or an MBE method (molecular beam vapor phase epitaxial method), that can grow a nitride semiconductor, may be used.

### <Insulating Structural Member (Guide Portion)>

As the material for the guide portions 14, an insulating material having a higher resistivity than that of the phosphor particles 15 and superior adhesion to the back electrode 12 is preferably used. Examples thereof include: SiNₓ, SiO₂, TiO₂, Al₂O₃, and a silicon polymer, such as silsesquioxane.

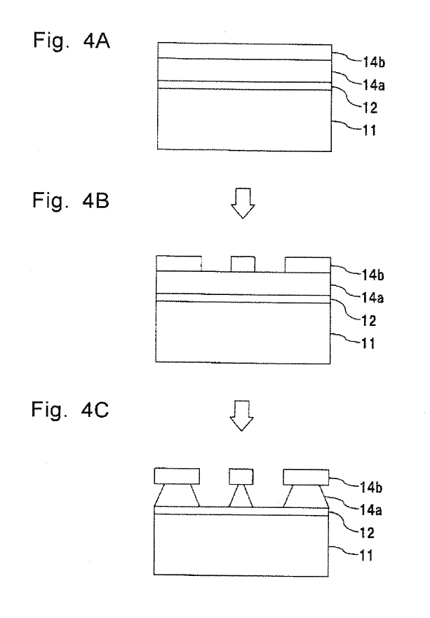

As the formation method for the guide portions 14, selection can be properly made among a photolithography method, an ink-jet method, a sandblasting method, a gravure printing method and the like, according to factors such as the size of the phosphor particles 15 and the size of a light emitting area (pixel region), and the photolithography method is preferably used. FIGS. 4A to 4C show one example of a sequence of formation processes of the guide portions 14.

(1) An insulating film 14a (SiNₓ or the like) is formed on a back electrode 12 (Mo or the like) formed on a substrate by using a chemical vapor deposition (CVD) method (FIG. 4A).
(2) On the insulating film 14a, a resist film 14b is formed by using a resist coater.
(3) The resulting film is pattern-exposed by using a photomask so as to be developed so that an etching mask pattern is formed on the resist film 14b (FIG. 4B).
(4) The insulating film 14a is patterned by plasma dry etching (FIG. 4C).
(5) The remaining resist film 14b is separated.

Additionally, in a light emitting element array or the like, disposed two-dimensionally by using a plurality of light emitting elements 10 shown in FIG. 1, when barrier ribs are required between the light emitting elements (pixels), those ribs may be simultaneously formed by using the same material as that of the guide portions.

### <Effects>

In the light emitting element in accordance with first embodiment of the present invention, since an electric field can be applied substantially perpendicularly to the non-polar plane of each phosphor particle, it becomes possible to achieve a light emitting element with high luminance and high efficiency, with influences of an inner electric field generated in a direction perpendicular to the polar plane being eliminated. Moreover, it is possible to achieve a light emitting element that is easily formed into a plane shape.

### Example 1

In the following, a method for manufacturing a light emitting element in accordance with example 1 will be described.

### <Formation Method of Phosphor Particles>

First, a method for forming phosphor particles will be described.

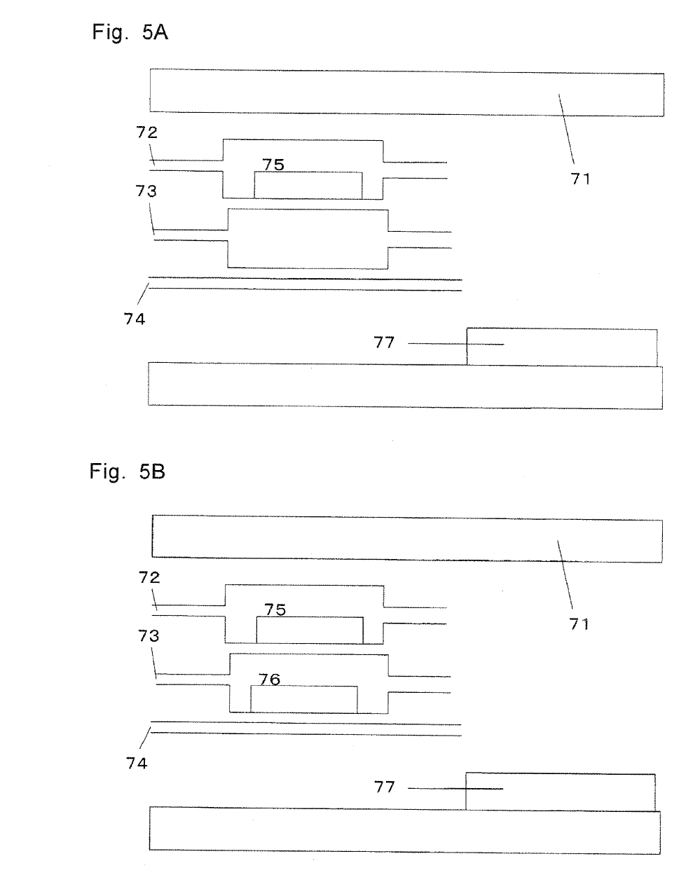

(a) A sapphire substrate with a diameter of 5.08 cm (2 inches) having a plane orientation (0, 0, 0, 1) was used as an epitaxial substrate. On the sapphire substrate, an SiO₂ film having a thickness of 5 μm was formed as an epitaxial mask by using a sputtering method, with a formation mask being interposed therebetween. An SiO₂ target was used as the target, and the sputtering process was carried out in an Ar gas atmosphere so as to form the film. The diameter of pore portions of the epitaxial mask was 3 μm.
(b) An AlN film was formed thereon by sputtering as a nucleus. An Al target was used as the target, and the sputtering was carried out in an N₂ gas atmosphere so as to form the film. The AlN film grew in the c-axis direction, with a thickness of 5 μm.
(c) The epitaxial substrate on which an epitaxial mask and nuclei had been formed was immersed in a 3% aqueous hydrofluoric acid solution so that the epitaxial mask was removed.
(d) On the epitaxial substrate on which only the nuclei had been formed, a non-doped GaN layer was formed around each nucleus as an n-type nitride semiconductor layer by using a halide vapor phase epitaxy (HVPE) method. The processes will be described in detail referring to FIG. 5A.

1) Through a gas line A 72, HCl was allowed to flow at a flow rate of 3 cc/min, and N₂ was also allowed to flow at a flow rate of 250 cc/min, with Ga metal 75 being placed in the mid way. Nothing was allowed to flow through a gas line B 73, and NH₃ was allowed to flow through a gas line C 74 at a flow rate of 250 cc/min. Moreover, through the entire portions of a furnace, N₂ was allowed to flow at a flow rate of 3000 cc/min.

2) The temperature of a reaction furnace 71 was set to 1000° C., and a non-doped GaN film was grown for 2 minutes so as to have a film thickness of 2 μm as an n-type semiconductor layer.

(e) After an n-type semiconductor layer (non-doped GaN layer) had been formed on each nucleus, a p-type semiconductor layer was formed thereon. Referring to FIG. 5B, these processes will be explained.

1) Through the gas line A 72, HCl was allowed to flow at a flow rate of 3 cc/min, and N₂ was also allowed to flow at a flow rate of 250 cc/min, with Ga metal 75 being placed in the mid way. MgCl₂ powder 76 was placed in a gas line B 73, and an N₂ gas was allowed to flow at a flow rate of 250 cc/min. Through a gas line C 74, NH₃ was allowed to flow at a flow rate of 250 cc/min. Moreover, through the entire portions of a furnace, N₂ was allowed to flow at a flow rate of 3000 cc/min.

2) The temperature of the reaction furnace 71 was set to 1000° C., and a GaN film doped with Mg was grown for two minutes so as to have a film thickness of 2 μm.

3) After the reaction, the temperature was lowered, with N₂ being allowed to flow through the entire portions of the inside of the furnace at a flow rate of 3000 cc/min, and when the temperature dropped to 700° C., this temperature was kept for one hour, and the temperature of the inside of the furnace was then again lowered.

Thus, a p-type semiconductor layer made of the GaN film doped with Mg was formed.

(f) Thereafter, with mechanical vibrations being given thereto, phosphor particles were taken out of the epitaxial substrate.

### <Method for Manufacturing Light Emitting Element>

In the following, a method for manufacturing a light emitting element in which the phosphor particles are used will be described.

(a) On a glass substrate, a back electrode having a laminated Mo/Cr structure was formed, and stripe-shaped guide portions made from SiNₓ were formed by using the above-mentioned sequence of forming processes. The gap between adjacent guide portions was set to 3 μm, the height of the guide portions was set to 3 μm, and the width of the bottom side of each guide portion was set to 5 μm.
(b) The phosphor particles were formed into a paste together with the insulating resin, and after having been dropped on the back electrode, the paste was squeezed in parallel with the elongating direction of the guide portions by using a rubber blade. Portions at which there were lacks of the aligned phosphor particles were allowed to ensure the insulating property thereof by the above-mentioned insulating resin.
(c) As the upper electrode, a glass substrate with an ITO electrode formed thereon was prepared, and this was used together with the above-mentioned glass substrate so as to sandwich the phosphor particles so that an EL confirming element was manufactured.

A direct current was applied between the electrodes of this EL confirming element for evaluation; thus, the resulting luminance was 1.5 times higher than that of comparative example 1, which will be described later.

### Comparative Example 1

Comparative example 1 was different from example 1 in that, without installing the guide portions, a back electrode on which only phosphor particles had been dispersed was sandwiched between two glass substrates so that an EL confirming element was prepared.

### Second embodiment

### <Outline Structure of Light Emitting Element>

A light emitting element 20 in accordance with second embodiment of the present invention will be described referring to FIG. 2. FIG. 2 is a cross-sectional view perpendicular to a phosphor layer, which illustrates a schematic structure of the light emitting element 20 of second embodiment. The light emitting element 20 is different from the light emitting element 10 shown in FIG. 1 in that a hole transporting layer 21 is further installed between the back electrode 12 and the phosphor layer 13. The light emitting element 20 of second embodiment is characterized in that the hole injecting property to the phosphor particles 15 is improved by the hole transporting layer 21.

Additionally, without limited to the above-mentioned structure, other revised structures, such as that in which the polarities of the electrodes are positive/negative reversed, that in which a reflective film is further formed between the guide portion 14 and the hole transporting layer 21, that in which a member for sealing the entire or a portion of the light emitting element 20 with a resin material or a ceramic material is further provided, that in which a member for color-converting or filtering a light emission color from the phosphor layer 13 is further placed on the front side in the light emission taking-out direction, and that in which, by changing the substrate 11 to a transparent substrate, with the back electrode 12 being changed to a transparent electrode, light emission is taken out from below the light emitting element 10, may be used.

### <Hole Transporting Layer>

As the hole transporting layer 21, an organic material or an inorganic material having a high hole mobility is used. The organic material for the hole transporting layer 21 is mainly classified into low molecular materials and high molecular materials. Examples of the low molecular material having the hole transporting property include: diamine derivatives, such as N,N′-bis(3-methylphenyl)-N,N′-diphenylbenzidine (TPD) and N,N′-bis(α-naphthyl)-N,N′-diphenylbenzidine (NPD). Moreover, multimers (oligomers) including these structural units may also be used. Examples also include those materials having a spiro structure or a dendrimer structure. Moreover, a mode in which a low-molecular-based hole transporting material is molecule-dispersed in a non-conductive polymer may also be used. Specific examples of the molecule-dispersed materials include a material in which TPD is molecule-dispersed in polycarbonate with high concentration, and its hole mobility is in a range from about 10⁻⁴ to 10⁻⁵ cm²/Vs. As the polymer-based material having a hole transporting property, π conjugated polymers and a conjugated polymers are proposed, and for example, those in which an arylamine-based compound or the like is incorporated are proposed. Specific examples thereof include: a poly-para-phenylene vinylene derivative (PPV derivative), a polythiophene derivative (PAT derivative), a polyparaphenylene derivative (PPP derivative), polyalkylphenylene (PDAF), a polyacetylene derivative (PA derivative), and a polysilane derivative (PS derivative), but are not limited thereto. Moreover, a low molecular-based polymer in which a molecular structure that exhibits a hole transporting property is incorporated in a molecule chain thereof may be used, and specific examples of these include: a polymethacryl amide (PTPAMMA, PTPDMA) having an aromatic amine in its side chain, and a polyether (TPDPES, TPDPEK) having an aromatic amine in its main chain. Among these, a particularly desirable example is poly-N-vinylcarbazole (PVK), which exhibits an extremely high hole mobility of 10⁻⁶ cm²/Vs. Other specific examples include PEDOT/PSS and polymethylphenyl silane (PMPS). Moreover, a plurality of kinds of the above-mentioned hole transporting materials may be mixed with one another and used. Furthermore, a crosslinkable or polymerizable material that can be crosslinked or polymerized by light or heat may be contained therein.

As the inorganic material for the hole transporting layer 21, semimetal-based semiconductors, such as Si, Ge, SiC, Se, SeTe, and As₂Se₃, binary compound semiconductors, such as ZnSe, CdS, ZnO, CuI, and Cu₂S, chalcopyrite-type semiconductors, such as CuGaS₂, CuGaSe₂, and CuInSe₂, and mixed crystals of these, may be used, and oxide semiconductors, such as CuAlO₂ and CuGaO₂, and mixed crystals of these may also be used. Moreover, in order to control the conductivity thereof, a dopant may be added to these materials.

### <Effects>

In the same manner as in the light emitting element of first embodiment, the present embodiment makes it possible to provide a light emitting element that can achieve high luminance and high efficiency, and can be easily formed into a plane shape.

### Example 2

In example 2, the same procedure as that of example 1 was carried out except that, after guide portions had been formed, an organic hole transporting material (tetraphenyl butadiene-based derivative) was vapor-deposited, so that an EL confirming element was formed. When a direct-current voltage was applied between the electrodes of the resulting EL confirming element for evaluation, the resulting luminance was 1.6 times higher than that of comparative example 1.

### Third Embodiment

### <Outline Structure of Light Emitting Element>

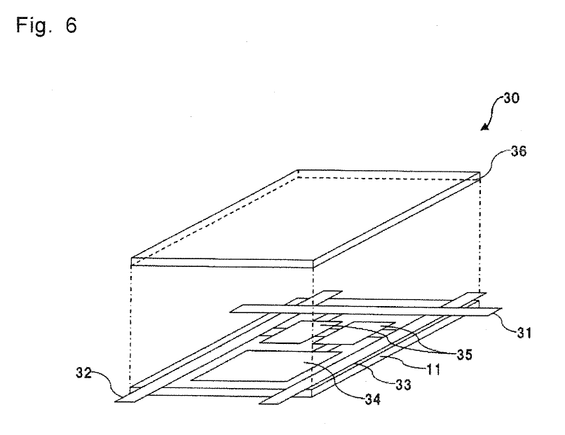

A light emitting element 30 in accordance with third embodiment of the present invention will be described referring to FIG. 6. FIG. 6 is a perspective view that illustrates a schematic structure of the light emitting element 30. The light emitting element 30 is further provided with a thin-film transistor (hereinafter, referred to simply as a “TFT”. FIG. 6 shows a two-component structure of a switching TFT and a driving TFT) 35 that is connected to a pixel electrode 34. A scanning line 31, a data line 32 and a current-supply line 33 are connected to the TFT 35. In this light emitting element 30, since light emission is taken out from a transparent common electrode 36 side, a large aperture ratio can be obtained independent of the layout of the TFT 35 on the substrate 11. Moreover, by using the TFT 35, the light emitting element 30 is allowed to have a memory function. As the TFT 35, an organic TFT made from an organic material, such as low-temperature polysilicon, an amorphous silicon TFT or pentacene, and an inorganic TFT made from ZnO, InGaZnO₄ or the like, may be used. Without limited to the above-mentioned structure, other revised structures, such as that in which a member for sealing the entire or a portion of the light emitting element 30 with a resin material or a ceramic material is further provided, that in which a member for color-converting or filtering a light emission color is further placed on the front side in the light emission taking-out direction, and that in which, by changing the substrate 11 to a transparent substrate, with the pixel electrode 34 being changed to a transparent electrode, light emission is taken out from below the light emitting element 30, may be used.

### <Effects>

In the same manner as in the light emitting element of first embodiment, the light emitting element in accordance with third embodiment makes it possible to provide a light emitting element that can achieve high luminance and high efficiency, and can be easily formed into a plane shape.

### Fourth Embodiment

### <Outline Structure of Display Device>

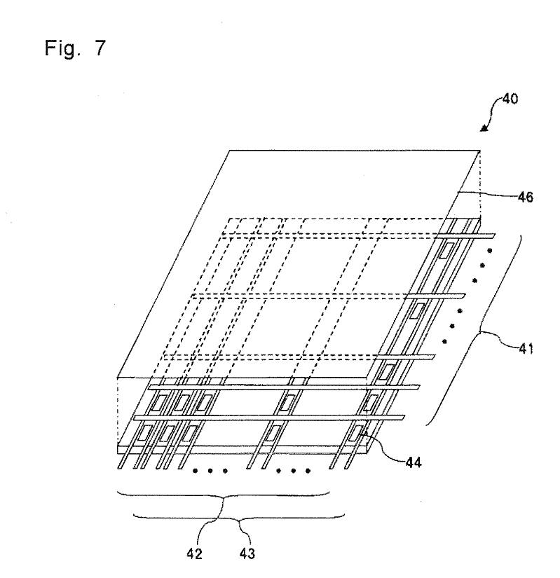

A display device 40 in accordance with fourth embodiment of the present invention will be described referring to FIG. 7. FIG. 7 is a schematic plan view that illustrates an active matrix-type display device 40 in which a pixel is composed of a pixel electrode 44 and a common electrode 46. This active matrix-type display device 40 is provided with a light emitting element array in which light emitting elements 30, as shown in FIG. 6, are two-dimensionally arranged, a plurality of scanning lines 41 that are extended in parallel with one another in a first direction that is in parallel with the surface of the light emitting element array, a plurality of data lines 42 that are extended in parallel with one another in a second direction that is in parallel with the surface of the light emitting element array and is orthogonal to the first direction, and a plurality of current supply lines 43 that are extended in parallel with the second direction. On the light emitting element array, each TFT (omitted in FIG. 7) is electrically connected to the scanning line 41, the data line 42 and the current supply line 43. A light emitting element, specified by the paired scanning line 41 and data line 42, forms a single pixel. Moreover, in this active matrix-type display device 40, an electric current is supplied from the current supply line 43 to one pixel selected by the scanning line 41 and the data line 42 through the TFT so that the selected light emitting element is driven, and the resulting light emission is taken out from the transparent common electrode 46 side. Without limited to the above-mentioned structure, by forming the substrate 11 into a transparent substrate, as well as by forming the pixel electrode 44 into a transparent electrode, the light emission may be taken out from below the display device 40.

Moreover, in the case of a color display device, the phosphor layer can be formed in a color-divided manner by using phosphor particles having respective colors of RGB. Alternatively, light emitting units, each composed of an electrode/a phosphor layer/an electrode, may be laminated for respective colors of RGB. Furthermore, in the case of a color display device of another example, after the display device has been formed by using a single-color or two-color phosphor layer, the respective colors of RGB can be displayed by using a color filter and/or a color-conversion filter. For example, by attaching color-converting filters that can change colors from blue to green, or from blue or green to red to the phosphor layer of blue color, it becomes possible to display RGB colors.

### <Effects>

In accordance with the display device of the present fourth embodiment, on the phosphor layers forming light emitting elements of the respective pixels, an electric field can be applied substantially perpendicularly to a non-polar plane of each of the phosphor particles; therefore, it becomes possible to achieve a display device with high luminance and high efficiency, with influences of an inner electric field generated in a direction perpendicular to the polar plane being eliminated. Moreover, it is possible to achieve a display device that is easily designed to have a large screen.

### Fifth Embodiment

### <Outline Structure of Display Device>

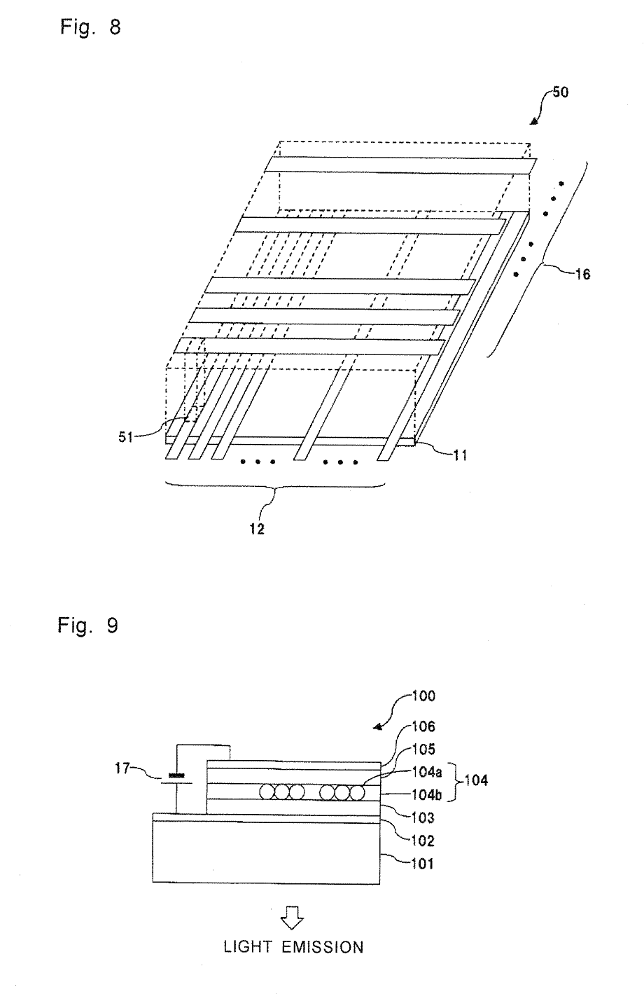

A display device 50 in accordance with fifth embodiment of the present invention will be described referring to FIG. 8. FIG. 8 is a schematic perspective view that illustrates a passive matrix-type display device 50 that is constituted of back electrodes 12 and transparent electrodes 16 that are orthogonal to each other. This passive matrix-type display device 50 is provided with a light emitting element array in which a plurality of light emitting elements, shown in FIG. 1 or FIG. 2, are two-dimensionally arranged. Moreover, this device is further provided with a plurality of back electrodes 12 that are extended in parallel with a first direction that is in parallel with the surface of the light emitting element array, and a plurality of transparent electrodes 16 that are extended in parallel with a second direction that is orthogonal to the first direction, and also made in parallel with the surface of the light emitting element array. In the passive matrix-type display device 50, an external voltage is applied between the paired back electrode 12 and transparent electrode 16 so that one light emitting element is driven, and the resulting light emission is taken out from the transparent electrode 16 side. Without limited to the above-mentioned structure, by forming the substrate 11 into a transparent substrate, as well as by forming the back electrode 12 into a transparent electrode, the light emission may be taken out from below the display device 50.

### <Effects>

In accordance with the display device of the present fifth embodiment, it becomes possible to achieve a display device that has high luminance and high efficiency, and is easily designed to have a large screen, in the same manner as in the above-mentioned fourth embodiment. Moreover, in the same manner as in the above-mentioned fourth embodiment, a color display device is also available.

With the light emitting element and image display device of the present invention, light emission with high luminance and high efficiency can be obtained. In particular, the present invention is effectively used as display devices, such as televisions, and as various kinds of light sources for use in communication, illumination and the like.

While the invention has been shown and described in detail by the preferred embodiments thereof, the present invention is not intended to be limited to these, and it is therefore obvious that numerous other modifications and variations as known to one having ordinary skill in the art can be devised without departing from the scope of the invention described in the following claims.

### EXPLANATION OF REFERENCE NUMERALS

10 Light emitting element, 11 Substrate, 12 Back electrode, 13 Phosphor layer, 14 Guide portion,
14a Insulating layer, 14b Resist film, 15 Phosphor particle, 15a n-type nucleus particle, 15b p-type epitaxial layer, 16 Transparent electrode, 17 Power supply,
20 Light emitting element, 21 Hole transporting layer, 30 Light emitting element, 31 Data line, 32 Scanning line, 33 Current-supply line, 34 Pixel electrode,
35 Thin-film transistor, 36 Common electrode,
40 Display device, 41 Scanning line, 42 Data line, 43 Power supply line,
44 Pixel electrode, 46 Common electrode, 50 Display device, 51 Pixel, 71 Reaction furnace, 72 Gas line A, 73 Gas line B, 74 Gas line C, 75 Ga metal, 76 MgCl₂ powder,
77 Substrate, 100 Light emitting element, 101 Substrate, 102 Anode, 103 Hole transporting layer,
104 Phosphor layer, 104a Semiconductor nano crystal, 104b Filling substance, 105 Electron transporting layer, 106 Cathode, 107 Power supply

1. A light emitting element comprising:
a first electrode and a second electrode provided as being opposed each other, at least one of the first electrode and the second electrode being transparent or translucent; and
a phosphor layer sandwiched between the first electrode and the second electrode, from a direction that is perpendicular to main surfaces of the first and second electrodes,
wherein the phosphor layer comprising:
a plurality of phosphor particles that are disposed within a plane of the phosphor layer; and
a first and second insulating guides that sandwich two sides of each of the phosphor particles from a direction that is in parallel with the surface of the phosphor layer.

2. The light emitting element according to claim 1, wherein the phosphor particles are disposed such that the longitudinal direction of each phosphor particle is in parallel with the surface of the phosphor layer, and
the first and second insulating guides sandwich the two sides in a direction that is perpendicular to the longitudinal direction of each of the phosphor particles from directions in parallel with the surface of the phosphor layer.

3. The light emitting element according to claim 1, wherein each of the phosphor particles is made of a compound semiconductor having a crystal structure of a hexagonal system.

4. The light emitting element according to claim 3, wherein each of the phosphor particles is made of a nitride semiconductor containing at least one element selected from the group consisting of Ga, Al and In.

5. The light emitting element according to claim 3, wherein each of the phosphor particles satisfies the relational expression such as L1<L2, L1 being a length of the phosphor particle along a direction that is in parallel with a c-plane and L2 being a length of the phosphor particle along a direction that is perpendicular to c-plane.

6. The light emitting element according to claim 3, wherein the c-axis direction of each of the phosphor particles is substantially in parallel with the surface of the phosphor layer.

7. The light emitting element according to claim 3, wherein the first and second insulating guides have a resistivity along a direction perpendicular to the surface of the phosphor layer being higher than a resistivity of each of the phosphor particles along a direction perpendicular to the surface of the phosphor layer.

8. The light emitting element according to claim 7, wherein each of the first and second insulating guides has a plane portion that is in parallel with the main surface of the electrode selected from the first electrode and second electrode, and
the plane portion has at least one portion thereof as being in contact with the main surface of the electrode.

9. The light emitting element according to claim 8, wherein the first insulating guide and the second insulating guide that sandwich the two sides of each of the phosphor particles have a gap that is wider than a width of the phosphor particle along a direction orthogonal to a c-axis of an m-plane of the phosphor particle.

10. The light emitting element according to claim 1, further comprising:
a hole transporting layer that is sandwiched between the phosphor particles and the electrode that is selected from the first electrode and the second electrode.

11. The light emitting element according to claim 1, further comprising:
a supporting substrate that faces at least one of the first electrode and the second electrode, and supports the first and second electrodes.

12. The light emitting element according to claim 11, further comprising: one or more thin-film transistors that are connected to at least one of the first electrode and the second electrode.

13. A display device comprising:
a light emitting element array on which the plurality of light emitting elements are two-dimensionally arranged, the light emitting element being claimed in claim 1;
a plurality of x electrodes that are extended in parallel with one another in a first direction in parallel with a light emitting surface of the light emitting array; and
a plurality of y electrodes that are extended in parallel with one another in a second direction orthogonal to the first direction, in parallel with the light emitting surface of the light emitting element array.

14. A display device comprising:
a light emitting element array on which the plurality of light emitting elements are two-dimensionally arranged, the light emitting element being claimed in claim 12
a plurality of signal lines that are extended in parallel with one another in a first direction in parallel with the light emitting surface of the light emitting element array; and
a plurality of scanning lines that are extended in parallel with a second direction orthogonal to the first direction, in parallel with the light emitting surface of the light emitting element array,
wherein one of the electrodes that are connected to the thin film transistor of the light emitting element array corresponds to a pixel electrode placed on each of intersections between the signal lines and the scanning lines, and
the other one of the electrodes is commonly provided on the plurality of light emitting elements.
